(19) United States
(12) Patent Application Publication
(10) Pub. No.: US 2016/0064695 A1
(43) Pub. Date: Mar. 3, 2016

(54) ORGANIC ELECTROLUMINESCENCE ELEMENT AND METHOD OF MANUFACTURING THE SAME

(71) Applicant: PANASONIC INTELLECTUAL PROPERTY MANAGEMENT CO., LTD., Osaka-shi, Osaka (JP)

(72) Inventors: Takaaki YOSHIHARA, Osaka (JP); Motonobu AOKI, Osaka (JP); Takashi ANJIKI, Osaka (JP)

(73) Assignee: PANASONIC INTELLECTUAL PROPERTY MANAGEMENT CO., LTD., Osaka (JP)

(21) Appl. No.: 14/786,310

(22) PCT Filed: Apr. 23, 2014
(86) PCT No.: PCT/JP2014/002277

§ 371 Date: Oct. 22, 2015

(30) Foreign Application Priority Data
May 9, 2013 (JP) 2013-099666

(51) Int. Cl. H01L 51/52; H01L 51/00; H01L 51/56

(52) U.S. Cl. CPC H01L 51/5275; H01L 51/56; H01L 51/0096; H01L 51/5271; H01L 51/5268; H01L 51/5246; H01L 2251/5315; H01L 2251/533

(57) ABSTRACT

The disclosure relates to an organic electroluminescence element including: a first substrate on a light extraction side thereof; a second substrate opposite the first substrate; and an organic light-emitting laminate between the first substrate and the second substrate. The first substrate includes a doped region in a surface close to the organic light-emitting laminate, the doped region being doped with a dopant for causing change in a refractive index of the first substrate to enhance a light-outcoupling efficiency.

### TECHNICAL FIELD

The present disclosure relates to an organic electroluminescence element and a method of manufacturing the same.

### BACKGROUND ART

There has been generally known an organic electroluminescence element (hereinafter also referred to as “organic EL element”) having a structure in which, between a pair of substrates, an organic light-emitting laminate is situated, which is formed by stacking an anode, a hole transport layer, a light-emitting layer, an electron injection layer, a cathode, and the like. In the organic EL element, a voltage is applied between the anode and the cathode so that light emitted from the light-emitting layer emerges outside through a light-transmissive substrate.

In the organic EL element, it is important to increase an amount of light which is emitted from the light-emitting layer and emerges outside. In the organic EL element, in general, part of light traveling from the light-emitting layer toward the outside is confined inside the organic EL element due to total reflection caused by a refractive index difference or the like, and thus an emission amount of light to the outside is reduced. A rate of the amount of emerging light to the supplied electrical energy is defined as an light-outcoupling efficiency. Therefore, a structure for increasing the light-outcoupling efficiency is desired.

Attempts have been made to improve the light-outcoupling efficiency. As one attempt, there has been developed a method of changing the surface shape of the substrate arranged on the light extraction side from a flat surface. For example, JP 2004-164912 A discloses a technology of forming, on the light extraction side, a structure having recessed portions at positions where the light-emitting layer is not formed. However, in the method of this literature, the light-emitting layer and the uneven structure are not overlapped with each other, and hence it is difficult to effectively enhance the light-outcoupling efficiency of the organic EL element having a large light-emitting area.

### SUMMARY OF INVENTION

The objective of the present disclosure is to provide an organic electroluminescence element with an effectively improved light-outcoupling efficiency and a method of manufacturing the same.

The present disclosure relates to an organic electroluminescence element. The organic electroluminescence element includes: a first substrate on a light extraction side of the organic electroluminescence element; a second substrate opposite the first substrate; and an organic light-emitting laminate between the first substrate and the second substrate. The first substrate includes a doped region in a surface close to the organic light-emitting laminate, the doped region being doped with a dopant for causing change in a refractive index of the first substrate to enhance a light-outcoupling efficiency.

The present disclosure relates to a method of manufacturing an organic electroluminescence element. The method is suitable for manufacturing the above-mentioned organic electroluminescence element, and includes: implanting, into a surface of a first substrate, a dopant for causing change in a refractive index of the first substrate to enhance a light-outcoupling efficiency; and diffusing an implanted dopant.

According to the present disclosure, the doped region is present in the first substrate on the light extraction side, and hence the light-outcoupling efficiency may be effectively improved.

### BRIEF DESCRIPTION OF DRAWINGS

FIG. 1 is a sectional view for illustrating an example of an organic electroluminescence element.

FIG. 2 is a sectional view for illustrating another example of the organic electroluminescence element.

FIG. 3 is a sectional view for illustrating another example of the organic electroluminescence element.

FIG. 4 is a sectional view for illustrating another example of the organic electroluminescence element.

FIG. 5 is a sectional view for illustrating another example of the organic electroluminescence element.

FIG. 6 is a sectional view for illustrating another example of the organic electroluminescence element.

FIG. 7 is a sectional view for illustrating another example of the organic electroluminescence element.

FIG. 8A is a sectional view for illustrating an example of a first substrate. FIG. 8B is a sectional view for illustrating another example of the first substrate.

FIG. 9 is a sectional view for illustrating another example of the first substrate.

FIG. 10 is a sectional view for illustrating another example of the first substrate.

FIG. 11 is a sectional view for illustrating an example of a planar concentration distribution pattern.

FIG. 12A and FIG. 12B are sectional views for illustrating examples of patterns of the planar concentration distribution. FIG. 12A is an example of a quadrangular grid. FIG. 12B is an example of a hexagonal grid.

FIG. 13A to FIG. 13D are sectional views for illustrating an example of a method of manufacturing an organic electroluminescence element. FIG. 13A is an illustration of an unprocessed first substrate. FIG. 13B is an illustration of a roughened first substrate. FIG. 13C is an illustration of a first substrate doped with a dopant. FIG. 13D is an illustration of a first substrate with a melted surface.

FIG. 14A to FIG. 14F are sectional views for illustrating another example of the method of manufacturing an organic electroluminescence element. FIG. 14A is an illustration of an unprocessed first substrate. FIG. 14B is an illustration of a roughened first substrate. FIG. 14C is an illustration of a first substrate doped with a dopant. FIG. 14D is an illustration of a first substrate with a melted surface. FIG. 14E is an illustration of a structure in which a resin layer is formed on the first substrate. FIG. 14F is an illustration of a structure in which an organic light-emitting laminate is formed on the resin layer.

### DESCRIPTION OF EMBODIMENTS

The present disclosure relates to an organic electroluminescence element (organic EL element). The organic EL element includes a first substrate 1 on a light extraction side of the organic EL element, a second substrate 2 opposite the first substrate 1, and an organic light-emitting laminate 3 between the first substrate 1 and the second substrate 2. The first substrate 1 includes a doped region 1a in the surface close to the organic light-emitting laminate 3, and the doped region 1a is doped with a dopant for causing change in a refractive index of the first substrate 1 to enhance a light-outcoupling efficiency. In this organic EL element, the doped region 1a is formed in the first substrate 1 on the light extraction side, and hence total reflection of light emitted from a light-emitting layer can be suppressed. Therefore, the light-outcoupling efficiency can be easily and effectively improved.

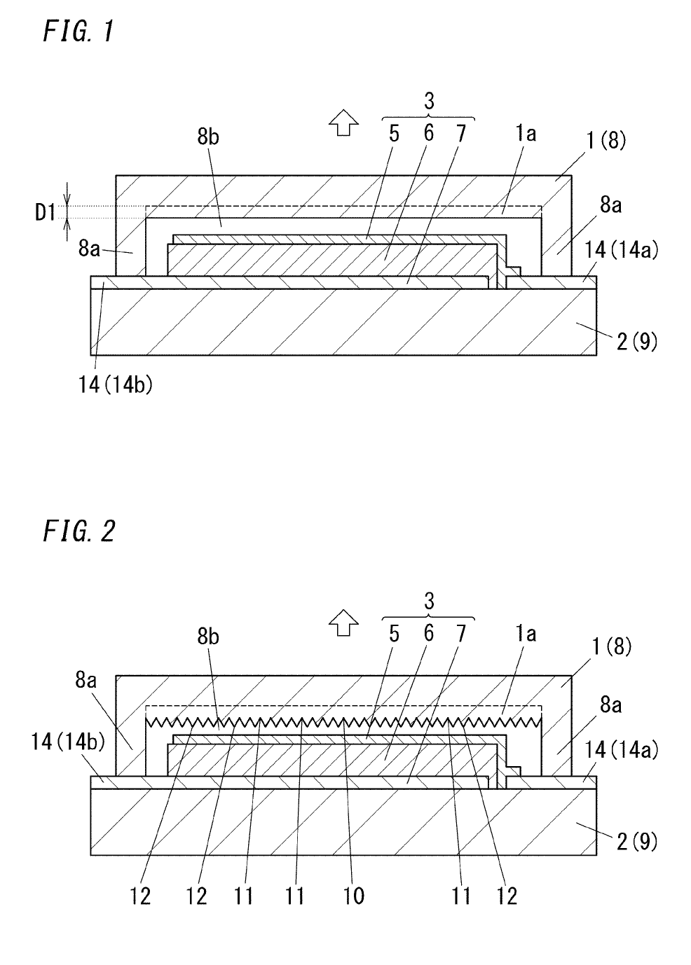

FIG. 1 shows an example of the organic electroluminescence element (organic EL element). The organic EL element includes the first substrate 1, the second substrate 2, and the organic light-emitting laminate 3.

The first substrate 1 is a substrate arranged on the light extraction side. The first substrate 1 is light transmissive. The second substrate 2 is a substrate which is opposite the first substrate 1. The expression “one substrate is opposite the other substrate” may mean that a surface of one substrate and a surface of the other substrate face each other. One of the first substrate 1 and the second substrate 2 serves as a support substrate 9, and the other of the first substrate 1 and the second substrate 2 serves as a enclosing substrate 8. In FIG. 1, the first substrate 1 serves as the enclosing substrate 8, and the second substrate 2 serves as the support substrate 9.

The support substrate 9 is a substrate for supporting the organic light-emitting laminate 3. In general, the organic light-emitting laminate 3 is formed by stacking two or more layers on the substrate. The support substrate 9 can be used as a formation substrate for forming the organic light-emitting laminate 3 by stacking layers thereon. The organic light-emitting laminate 3 is formed on a surface of the support substrate 9.

The enclosing substrate 8 is a substrate for enclosing the organic light-emitting laminate 3 formed on the support substrate 9. The organic light-emitting laminate 3 contains organic substances, and hence tends to deteriorate easily. For the purpose of suppressing such deterioration, a structure for protecting the organic light-emitting laminate 3 from moisture and air is required. Further, the organic light-emitting laminate 3 has a structure of a stack of thin films, and hence is sensitive to physical impacts. Therefore, a structure for protecting the organic light-emitting laminate 3 from external physical impacts is required. In view of this, the enclosing substrate 8 is designed to enclose the organic light-emitting laminate 3 to protect it.

The support substrate 9 and the enclosing substrate 8 may be flat-plate substrates. Accordingly, a planar organic EL element can be obtained. The planar organic EL element is useful as a planar illumination device.

In the organic EL element of FIG. 1, the first substrate 1 that is the substrate on the light extraction side serves as the enclosing substrate 8. Therefore, the element has a so-called top-emission structure. In FIG. 1 and subsequent figures, a direction in which light emerges outside is indicated by the outline arrow.

As described above, according to one preferable aspect, the second substrate 2 serves as the support substrate 9 for the organic light-emitting laminate 3, the first substrate 1 serves as the enclosing substrate 8 for enclosing the organic light-emitting laminate 3, and the organic EL element has a top-emission structure. Accordingly, it is possible to obtain an element which has a top-emission structure and yet has a high light-outcoupling efficiency.

The enclosing substrate 8 may include an enclosing side wall 8a. The enclosing side wall 8a is a part protruding from an outer periphery of the enclosing substrate 8 toward the support substrate 9. The enclosing side wall 8a can serve as a spacer for securing a space for the thickness of the organic light-emitting laminate 3, and can also suppress intrusion of moisture and air through a lateral side of the organic electroluminescence element, thereby being capable of enhancing performance of protecting the organic light-emitting laminate 3. The formation of the enclosing side wall 8a leads to formation of, at the center of the enclosing substrate 8, an accommodating recessed portion 8b for accommodating the organic light-emitting laminate 3. In general, the support substrate 9 and the enclosing substrate 8 are bonded to each other by a bonding layer formed at the enclosing side wall 8a.

The enclosing substrate 8 may not include the enclosing side wall 8a and thus may be an enclosing substrate 8 whose surface is entirely flat. In this case, the thickness of the bonding layer may be set to be equal to or larger than the thickness of the organic light-emitting laminate 3. In this manner, the bonding layer can serve as a spacer, and the organic light-emitting laminate 3 can be enclosed. When the enclosing substrate 8 whose surface is entirely flat is used, formation of the enclosing side wall 8a and the accommodating recessed portion 8b is not required, and a substrate with a flat surface can be used for enclosure. Therefore, the organic EL element can be manufactured more easily.

The second substrate 2 is a substrate on the opposite side of the organic electroluminescence element from the light extraction side, and may be or not be light transmissive. In a case of a double-sided extraction structure, however, the second substrate 2 is preferred to be light transmissive. Further, from the viewpoints of easiness in manufacture and external appearance, it is preferable the second substrate 2 be transparent.

The first substrate 1 and the second substrate 2 can be made of appropriate materials. The first substrate 1 is preferred to be formed of a glass substrate. Accordingly, light can be efficiently extracted to the outside. Further, forming the enclosing substrate 8 of a glass substrate enhances the sealing performance. The second substrate 2 is preferred to be formed of a glass substrate. Accordingly, the element can be manufactured easily. Further, forming the support substrate 9 of a glass substrate facilitates the formation of the organic light-emitting laminate 3 by stacking, and also enhances the sealing performance.

The organic light-emitting laminate 3 includes a first electrode 5, a second electrode 7, and an organic light-emitting layer 6 between the first electrode 5 and the second electrode 7. The first electrode 5 is an electrode closer to the first substrate 1. The second electrode 7 is an electrode closer to the second substrate 2. The organic light-emitting laminate 3 may be formed by stacking on the support substrate 9. In FIG. 1, the organic light-emitting laminate 3 is a laminate including the second electrode 7, the organic light-emitting layer 6, and the first electrode 5.

One of the first electrode 5 and the second electrode 7 serves as an anode, and the other thereof serves as a cathode. FIG. 1 shows a structure in which the second electrode 7 serves as the anode and the first electrode 5 serves as the cathode. Alternatively, it is possible to use a structure in which the second electrode 7 serves as the cathode and the first electrode 5 serves as the anode.

The first electrode 5 that is the electrode closer to the first substrate 1 is preferred to be a light-transmissive electrode. Accordingly, light can be extracted to the outside. The term “light-transmissive” means transparent or translucent.

The second electrode 7 that is the electrode closer to the second substrate 2 may be a light-reflective electrode. Accordingly, light traveling toward the opposite side of the organic electroluminescence element from the light extraction side can be reflected to change the direction of the light to travel toward the light extraction side, thereby being capable of easily enhancing the light-outcoupling efficiency. As a matter of course, the electrode closer to the second substrate 2 may be a light-transmissive electrode. In this case, an element having a double-sided extraction structure can be formed. Further, the electrode closer to the second substrate 2 may be a light-transmissive electrode, and a reflective film may be provided between this electrode and the second substrate 2. In this manner, a structure for enhancing the light-outcoupling efficiency can be formed.

The first electrode 5 and the second electrode 7 can be made of appropriate electrode materials. The first electrode 5 on the light extraction side may be formed of, for example, a metal thin film or a metal oxide film. The metal oxide film may be transparent and such a metal oxide film is preferably made of, ITO, IZO, AZO, or the like. The second electrode 7 can be formed of, for example, a metal layer having high reflectivity. Such a metal layer is preferably made of aluminum, silver, or the like.

The organic light-emitting layer 6 includes one or more layers appropriate for constituents of the organic EL element. The organic light-emitting layer 6 includes at least one luminescent material-containing layer. The luminescent material-containing layer is a layer containing a luminescent material. Holes injected from the anode and electrons injected from the cathode are combined in the luminescent material-containing layer and thereby light is produced. The light-emitting layer 6 may include a plurality of luminescent material-containing layers. With use of the plurality of luminescent material-containing layers, light of a desired color can be emitted. For example, with use of luminescent material-containing layers of three colors of red, green, and blue, white light emission can be obtained, thereby being capable of forming an organic EL element useful for illumination applications.

The organic light-emitting layer 6 is preferred to include a layer for enhancing the transport and injection performance of electric charges (holes and electrons). The organic light-emitting layer 6 can be structured to include a hole injection layer, a hole transport layer, an electron transport layer, an electron injection layer, and the like. Those layers are stacked in an order that enables transportation of electric charges to the light-emitting layer. Further, the organic light-emitting layer 6 may have a multi-unit structure. In the multi-unit structure, the organic light-emitting layer 6 can include an interlayer. The multi-unit structure is a structure obtained by stacking multiple light-emitting units in such a manner that one or more light transmissive and electrically conductive interlayers are interposed between each pair of adjacent two of the multiple light-emitting units. Each of the multiple light-emitting units has a laminate structure with a function of emitting light in response to voltage applied between an anode and a cathode positioned on opposite sides thereof. In the multi-unit structure, multiple light-emitting units which are stacked in the thickness direction and connected in series electrically are interposed between one anode and one cathode.

In the organic EL element, a voltage is applied between two electrodes to generate a current and cause light emission. Therefore, each electrode is required to extend outside from the enclosed part. In FIG. 1, electrode lead-out portions 14 are formed, which serve as parts respectively extended outside from the first electrode 5 and the second electrode 7. The electrode lead-out portions 14 are a first electrode lead-out portion 14a electrically connected to the first electrode 5, and a second electrode lead-out portion 14b electrically connected to the second electrode 7. The first electrode lead-out portion 14a and the second electrode lead-out portion 14b are not in physical contact with each other and are insulated from each other. Accordingly, a voltage can be applied without causing short-circuit failure.

The first electrode lead-out portion 14a is an electrode layer which includes a part in contact with the first electrode 5 inside the enclosed part and a part extending to the outside of the enclosing substrate 8. The electrode layer serving as the first electrode lead-out portion 14a may be formed by patterning a conductive layer for forming the second electrode 7. The second electrode lead-out portion 14b is a part extending from the second electrode 7 to the outside of the enclosing substrate 8. As described above, in the organic EL element, the first electrode 5 and the second electrode 7 are formed without being in direct contact with each other and patterned wires are formed so that a voltage can be applied from an external device. In this manner, short-circuit failure can be suppressed and therefore satisfactory light emission can be obtained. As a matter of course, FIG. 1 shows merely one example of the electrode lead-out structure, and other electrode structures (laminated structure and lead-out structure) may be employed.

In the organic EL element, the first substrate 1 includes the doped region 1a in the surface close to the organic light-emitting laminate 3. The doped region 1a is doped with a dopant for causing change in the refractive index of the first substrate 1 to enhance the light-outcoupling efficiency. The doped region 1a may be formed with use of the material of the first substrate 1 as a base material. Doping with the dopant enhances the light-outcoupling efficiency. When a substrate and an organic layer have a large refractive index difference, the amount of totally reflected light is increased, which reduces the light-outcoupling efficiency. As a countermeasure, the dopant may be used to reduce the refractive index difference between the first substrate 1 and the organic light-emitting layer 6. Therefore, the doped region 1a can suppress the total reflection, thereby being capable of enhancing the light-outcoupling efficiency.

A light-scattering dopant may be used for doping. In this case, total reflection can be suppressed by the scattering function of the dopant, thereby being capable of further enhancing the light-outcoupling efficiency.

In FIG. 1, the outer border of the doped region 1a (boundary line between the doped part and the undoped part) is indicated by the broken line. In the figures subsequent to FIG. 1 as well, unless otherwise noted, the region indicated by the broken line is similarly the doped region 1a.

In the doped region 1a, the dopant causes change in the refractive index of the first substrate 1. When the refractive index of the first substrate 1 is lower than the refractive index of the organic light-emitting layer 6, the first substrate 1 is doped with a dopant for increasing the refractive index of the first substrate 1. Accordingly, the refractive index difference is decreased. For example, in the case of a glass substrate and an organic layer, in general, the organic layer often has a higher refractive index, and hence the doped region 1a is formed in the surface of the glass substrate by doping the surface with a dopant for increasing the refractive index, which may decrease the refractive index difference. Note that, when the refractive index of the first substrate 1 is higher than the refractive index of the organic light-emitting layer 6, the first substrate 1 may be doped with a dopant for decreasing the refractive index of the first substrate 1. Accordingly, the refractive index difference is decreased. Note that, total reflection is likely to occur when light travels from a substance having a higher refractive index to a substance having a lower refractive index. Therefore, it is more advantageous to adopt a structure in which the refractive index of the first substrate 1 is lower than the refractive index of the organic light-emitting layer 6, and the doped region 1a is formed to increase the refractive index of the first substrate 1.

In the first substrate 1, the refractive index difference between the doped region 1a and a region other than the doped region 1a is preferred to be 0.1 or more in absolute value. Accordingly, the light-outcoupling efficiency can be further enhanced. In the first substrate 1, the refractive index difference between the doped region 1a and the region other than the doped region 1a is preferred to be 2 or less in absolute value. Accordingly, deterioration of the first substrate 1 due to an excess dopant can be suppressed. Note that, when the doped region 1a has a concentration distribution, the refractive index of the doped region 1a used for calculating the refractive index difference may be the average refractive index of the doped region 1a.

The dopant may be particles, ions, or the like. Examples of the particles include metal particles, metal oxide particles, metal nitride particles, and inorganic particles. Examples of the ions include metal ions. Specific examples of the dopant include Ag, Cu, TiO₂, ZnO, and other transition metals. The doped region 1a may contain a plurality of types of dopants.

The doped region 1a may be a region of the first substrate 1 as a base material, which contains the dopant in a dispersed manner. The doped region 1a is basically made of a material of the first substrate 1. Therefore, the dopant is preferred to have a small particle diameter. For example, the average particle diameter of the dopant is not particularly limited, but is preferred to be 1,000 nm or less. Accordingly, the dopant can enhance the light-outcoupling efficiency efficiently. The lower limit of the average particle diameter of the dopant is not particularly limited, but in order to enhance the light-outcoupling efficiency efficiently, the average particle diameter of the dopant is preferred to be 100 nm or more.

The doped region 1a is preferred to contain at least 1 vol % dopant. Accordingly, the light-outcoupling efficiency can be efficiently enhanced. The doped region 1a is preferred to contain at most 50 vol % dopant. Accordingly, deterioration of the first substrate 1 and reduction in strength due to the excess dopant can be suppressed.

The doped region 1a is formed as a surface layer of the first substrate 1. The thickness of the doped region 1a may be appropriately adjusted from the viewpoint of enhancing the light-outcoupling efficiency. The thickness of the doped region 1a may be 10 μm or less. When the thickness of the doped region 1a is too large, the first substrate 1 is likely to deteriorate or to decrease in strength. The thickness of the doped region 1a may be 0.1 μm or more. When the thickness of the doped region 1a is too small, the effect of enhancing the light-outcoupling efficiency is likely to decrease. In this case, the thickness of the doped region 1a is defined as a length in the thickness direction from the surface on a dopant region 1a side of the first substrate 1 to an innermost position where the dopant exists. In FIG. 1, the thickness of the doped region 1a is represented by D1.

In FIG. 1, the first substrate 1 serves as the enclosing substrate 8, and hence the doped region 1a is formed in the surface of the enclosing substrate 8 close to the organic light-emitting laminate 3. The doped region 1a is preferred to be formed so as to overlap in a plan view with the region on which the organic light-emitting laminate 3 is formed. Accordingly, the light-outcoupling efficiency can be enhanced. The plan view means a view of the organic EL element in a direction perpendicular to the light-emitting surface. In FIG. 1, the doped region 1a is formed in a bottom surface of the accommodating recessed portion 8b of the enclosing substrate 8. In this example, the doped region 1a is formed across the entire bottom surface of the accommodating recessed portion 8b. Therefore, the doped region 1a can be easily formed.

The doped region 1a is preferred to be integrated into the first substrate 1. Accordingly, the doped region 1a can be formed easier, and the light-outcoupling efficiency can be easily enhanced.

In FIG. 1, the doped region 1a is integrated into the first substrate 1. That is, the doped region 1a is formed by doping a part of a substrate material forming the first substrate 1 with a dopant. As described above, when the doped region 1a is integrated into the first substrate 1, the doped region 1a giving high light-outcoupling efficiency can be formed more easily. For example, the doped region 1a can be provided by bonding a substrate material doped with a dopant to the first substrate 1. However, in this case, the number of materials is increased, and hence the manufacture is likely to become complicated. Further, when a bonding layer is formed between the first substrate 1 and the substrate material for forming the doped region 1a, the bonding layer is likely to cause decrease in the light-outcoupling efficiency. Therefore, a structure in which the doped region 1a and the first substrate 1 are integrated with each other is more advantageous. In FIG. 1, for easy understanding of the integration of the doped region 1a with the first substrate 1, the boundary line between the doped region 1a and the other region is indicated by the broken line.

When the dopant is particles, the doped region 1a can be formed by spraying the particles on the surface of the first substrate 1, and then partially melting the first substrate 1, thereby diffusing the particles being the dopant inside. When the dopant is ions, the doped region 1a can be formed by irradiating the surface of the first substrate 1 with ions for ion implantation. As a matter of course, the doped region 1a may be formed by other methods.

A part between the first substrate 1 and the second substrate 2 other than the organic light-emitting laminate 3 (i.e., a part of the accommodating recessed portion 8b) may be filled with a filler, or may be hollow. When the inside of the sealed portion is filled with a filler, the organic EL element has a filled enclosed structure. When the inside of the enclosed portion is hollow, the organic EL element has a hollow enclosed structure. In the filled sealing structure, a resin may be used for filling. Filling with a resin enables formation of a resin layer. When the resin layer is formed between the first substrate 1 and the organic light-emitting laminate 3, the robustness can be enhanced. In the organic EL element having the hollow enclosed structure, depending on the element configuration, the first substrate 1 may sag toward the organic light-emitting laminate 3 and thus the first substrate 1 comes into contact with the organic light-emitting laminate 3, which may cause short-circuit failure. However, when the resin layer is formed between the first substrate 1 and the organic light-emitting laminate 3, the first substrate 1 is less likely to sag. Therefore, the contact between the first substrate 1 and the organic light-emitting laminate 3 can be suppressed, and occurrence of the short-circuit failure can be suppressed. As a matter of course, the hollow enclosed structure may be employed when there is no problem in short-circuit failure. The hollow enclosed structure offers an advantage in that the organic EL element can be manufactured more easily.

FIG. 2 shows another example of the organic EL element. The same components as the example of FIG. 1 are denoted by the same reference signs, and descriptions thereof are omitted herein. The organic EL element of FIG. 2 differs from the organic EL element of FIG. 1 in the surface shape of the first substrate 1. The remaining configurations may be similar to those of FIG. 1.

Like the element of FIG. 1, the organic EL element of FIG. 2 is a top-emission element. The first substrate 1 serves as the enclosing substrate 8. The second substrate 2 serves as the support substrate 9. Light is emitted through the first substrate 1.

The first substrate 1 is preferred to have an uneven structure 10 on the surface on the doped region 1a side. Accordingly, the total reflection can be further suppressed by the uneven structure 10, and hence the light-outcoupling efficiency can be further improved.

In FIG. 2, the first substrate 1 has the uneven structure 10 on the surface on the doped region 1a side. When the first substrate 1 has the uneven structure 10, light can be scattered by the uneven structure 10. Therefore, even if light strikes the first substrate 1 at an angle at which total reflection occurs in a case where there is no uneven structure 10, such light is directed toward the outside, thereby being capable of extracting a larger amount of light to the outside. Therefore, with the actions of the dopant and the uneven structure 10, the light-outcoupling efficiency can be further enhanced.

The uneven structure 10 is preferred to include a recessed portion 11 and a protruding portion 12. The uneven structure 10 is preferred to include a plurality of recessed portions 11 instead of one recessed portion 11. The uneven structure 10 is preferred to include a plurality of protruding portions 12 instead of one protruding portion 12. The uneven structure 10 including the plurality of recessed portions 11 and protruding portions 12 can enhances the light-outcoupling efficiency.

The bottom part of the recessed portion 11 is preferred to be shallower than the bottom of the doped region 1a in the thickness direction. The bottom part of the recessed portion 11 refers to a most-recessed part of the recessed portion 11. When the bottom part of the recessed portion 11 is deeper than the bottom of the doped region 1a, a region in which the doped region 1a is not formed is present, and hence the light extraction effect due to the dopant is likely to be reduced. Therefore, the thickness of the doped region 1a is preferred to be larger than the depth of the recessed portion 11.

The sizes of the recessed portion 11 and the protruding portion 12 are not particularly limited, but the diameters of one recessed portion 11 and one protruding portion 12 in a plan view may be set within a range of from 0.01 μm to 100 μm. The depth of the recessed portion 11 or the height of the protruding portion 12, that is, the recess-protrusion height of the uneven structure 10 is not particularly limited, but may be set within a range of from 0.01 μm to 100 μm. The nano-sized or micro-sized fine recesses and protrusions can further enhance the scattering performance.

The recesses and protrusions in the uneven structure 10 may be regular recesses and protrusions or irregular recesses and protrusions. The regular recesses and protrusions may form a diffraction structure, thereby being capable of enhancing the light-outcoupling efficiency. The irregular recesses and protrusions do not have angular dependence, and hence light of a desired color can be extracted outside.

The uneven structure 10 can be obtained by roughening the surface of the first substrate 1 by appropriate processing methods such as blasting, melting, and etching. Among them, blasting of performing blast processing with particles is preferred, and sand-blasting of performing blast processing with sand is more preferred. Accordingly, the uneven structure 10 can be easily formed.

In FIG. 2, the recessed portion 11 in the uneven structure 10 has a triangular shape in cross section. The protruding portion 12 in the uneven structure 10 has a triangular shape in cross section. Then, the uneven structure 10 has a zig-zag shape in cross section. As a matter of course, the uneven shape of the uneven structure 10 is not limited thereto, and an appropriate shape can be employed. For example, the recessed portion 11 may be formed into a square-pyramid shape or a cone shape.

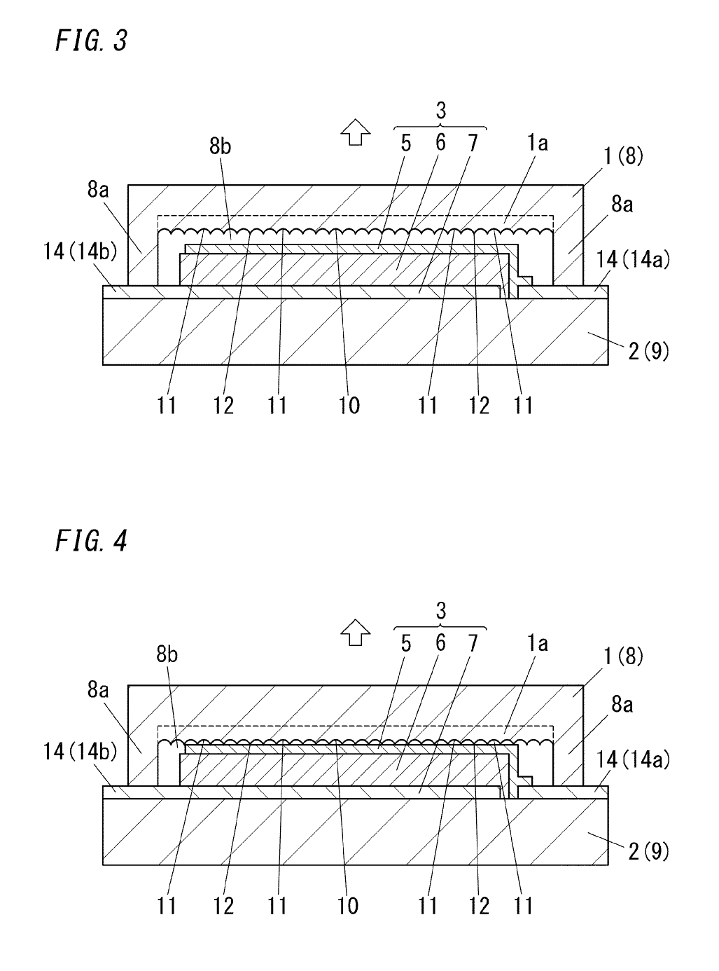

FIG. 3 shows another example of the organic EL element. The same components as the example described above are denoted by the same reference signs, and descriptions thereof are omitted herein. The organic EL element of FIG. 3 differs from the organic EL element of FIG. 2 in the shape of the uneven structure 10 formed in the first substrate 1. The remaining configurations may be similar to those of FIG. 2.

The organic EL element of FIG. 3 is a top-emission element, similarly to the element of FIG. 2. The first substrate 1 serves as the enclosing substrate 8. The second substrate 2 serves as the support substrate 9. Light is extracted through the first substrate 1.

In FIG. 3, the first substrate includes the uneven structure 10 on the surface on the doped region 1a side. When the first substrate 1 has the uneven structure 10, light can be scattered by the uneven structure 10. Therefore, even if light strikes the first substrate 1 at an angle at which total reflection occurs in a case where there is no uneven structure 10, such light is directed toward the outside, thereby being capable of extracting a larger amount of light to the outside. Therefore, with the actions of the dopant and the uneven structure 10, the light-outcoupling efficiency can be further enhanced.

The uneven structure 10 is preferred to include the plurality of recessed portions 11 curved inwardly of the first substrate 1. Accordingly, the total reflection can be further suppressed by the recessed portions 11, and hence the light-outcoupling efficiency can be further improved.

In FIG. 3, the uneven structure 10 has the plurality of recessed portions 11 curved inwardly of the first substrate 1. As described above, when the recessed portion 11 has a curved surface, the recessed portion 11 is shaped close to a lens, and hence the light scattering action can be enhanced. Therefore, the light-outcoupling efficiency can be further improved. The recessed portion 11 may have a hemispherical shape or a semi-ellipsoidal shape. In this case, the lens action is enhanced, thereby being capable of extracting a larger amount of light to the outside. It may be said that, considering in cross section, the recessed portion 11 may have a semi-circular shape or a semi-elliptical shape in cross section.

The curved recessed portion 11 can be formed by, for example, roughly forming the uneven structure 10 by sand blasting or the like, and then slightly melting the uneven surface to the extent that the recesses and protrusions do not lose their own inherent properties.

FIG. 4 shows another example of the organic EL element. The same components as the examples described above are denoted by the same reference signs, and descriptions thereof are omitted herein. The organic EL element of FIG. 4 differs from the organic EL element of FIG. 3 in the positional relationship between the first substrate 1 and the organic light-emitting laminate 3. The remaining configurations may be similar to those of FIG. 3.

The organic EL element of FIG. 4 is a top-emission element, similarly to the element of FIG. 3. The first substrate 1 serves as the enclosing substrate 8. The second substrate 2 serves as the support substrate 9. Light is extracted through the first substrate 1.

Also in FIG. 4, the first substrate 1 includes the uneven structure 10 on the surface on the doped region 1a side. The uneven structure 10 may be the same as that in the case of FIG. 3. That is, the recessed portion 11 can be formed into a curved shape.

In a preferable example of the uneven structure 10, the protruding portions 12 are in contact with the organic light-emitting laminate 3. Accordingly, the deformation of the first substrate 1 can be suppressed to enhance the robustness, thereby being capable of improving the reliability.

In FIG. 4, the protruding portions 12 in the uneven structure 10 are in contact with the organic light-emitting laminate 3. Accordingly, the surface of the first substrate 1 is supported on the organic light-emitting laminate 3. Therefore, the deformation of the first substrate 1 can be suppressed to enhance the robustness, thereby being capable of improving the reliability. Further, the distance between the first substrate 1 and the organic light-emitting laminate 3 shows a substantially uniform distribution in terms of the entire surface, and hence the uneven surface can become parallel to the light-emitting surface. Therefore, the optical axis can be easily adjusted, and the luminous efficiency can be effectively enhanced.

In the example of FIG. 4, the plurality of protruding portions 12 are formed, and the plurality of protruding portions 12 are each in contact with the organic light-emitting laminate 3. The closest layer of the organic light-emitting laminate 3 to the first substrate 1 is the first electrode 5. Therefore, the first electrode 5 and the protruding portions 12 are in contact with each other. When the plurality of protruding portions 12 are in contact, stress concentration can be suppressed, and damage on the organic light-emitting laminate 3 caused by the protruding portions 12 can be suppressed.

In the organic EL element, depending on the element configuration, the first substrate 1 may sag toward the organic light-emitting laminate 3, and thus the first substrate 1 presses the organic light-emitting laminate 3, which may cause short-circuit failure. The first substrate 1 is more likely to sag in the hollow sealing structure. However, when the first substrate 1 and the organic light-emitting laminate 3 are preliminarily in contact with each other, the first substrate 1 is fixed on the organic light-emitting laminate 3, and hence the first substrate 1 is less likely to sag. Therefore, excess pressing of the organic light-emitting laminate 3 by the first substrate 1 can be suppressed, and thus occurrence of the short-circuit failure can be suppressed.

The leading end of the protruding portion 12 is preferred to be rounded. Accordingly, damage on the organic light-emitting laminate 3 due to the contact between the protruding portions 12 and the organic light-emitting laminate 3 can be suppressed, and thus the reliability can be enhanced. The round leading end of the protruding portion 12 can be formed by melting.

The protruding portions 12 and the organic light-emitting laminate 3 can be brought into contact with each other by adjusting the thickness of the bonding layer formed between the enclosing side wall 8a of the first substrate 1 (enclosing substrate 8) and the second substrate 2 (support substrate 9). In general, the element is sealed by bonding together the first substrate 1 and the second substrate 2 with an adhesive for forming the bonding layer. Therefore, the contact state can be obtained by: adjusting the amount of the adhesive; or bringing the first substrate 1 and the second substrate 2 close to each other at the time of bonding and fixing the first substrate 1 to the second substrate 2 when the protruding portions 12 of the first substrate 1 are in contact with the organic light-emitting laminate 3.

Note that, in FIG. 4, the uneven structure 10 is illustrated with the recessed portions 11 having a semi-circular shape or a semi-elliptical shape in cross section as that in FIG. 3. As a matter of course, an example including the uneven structure 10 with the recessed portions 11 having a triangular shape in cross section as that in FIG. 2 may have the above contact structure of the protruding portions 12.

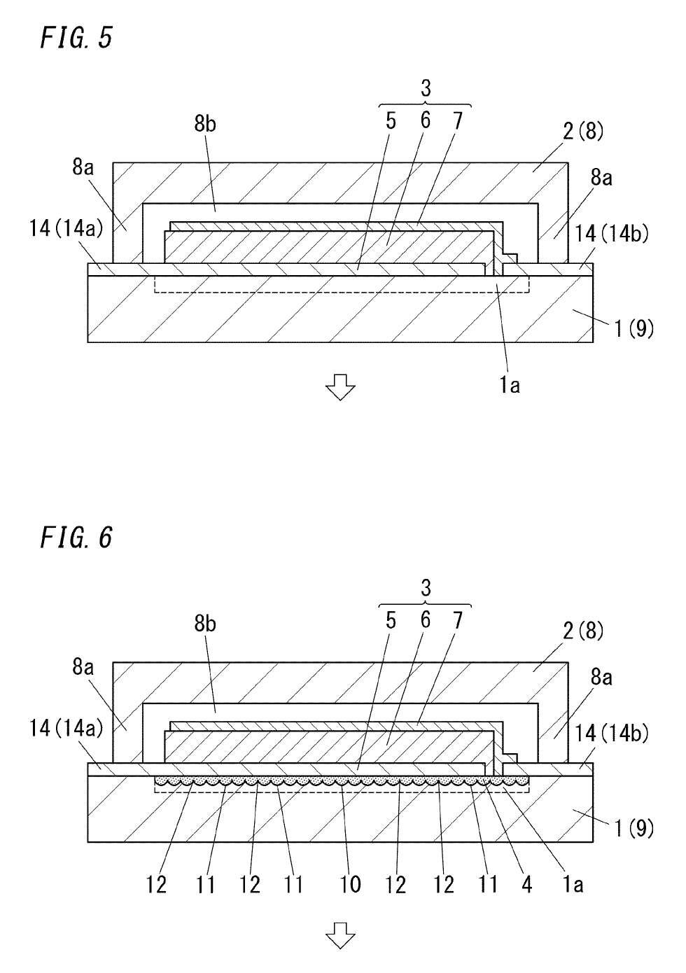

FIG. 5 shows another example of the organic EL element. The same components as the examples described above are denoted by the same reference signs, and descriptions thereof are omitted herein.

The organic EL element of FIG. 5 is a bottom-emission element unlike the mode of FIG. 1. The first substrate 1 serves as the support substrate 9. The second substrate 2 serves as the enclosing substrate 8. Light is extracted through the first substrate 1. The outline arrow indicates the light exiting direction.

As described above, in a preferable example, the first substrate 1 serves as the support substrate 9 for the organic light-emitting laminate 3, the second substrate 2 serves as the enclosing substrate 8 for enclosing the organic light-emitting laminate 3, and the organic EL element has a bottom-emission structure. Accordingly, a bottom-emission element having a high light-outcoupling efficiency can be obtained.

In FIG. 5, the first substrate 1 is the support substrate 9, and hence the organic light-emitting laminate 3 is formed by stacking layers on the surface of the first substrate 1. That is, on the first substrate 1, the first electrode 5, the organic light-emitting layer 6, and the second electrode 7 are stacked in the stated order. The enclosing side wall 8a extends from the outer peripheral portion of the second substrate 2 that is the enclosing substrate 8.

Also in the bottom-emission organic EL element, the first substrate 1 includes the doped region 1a. Accordingly, the light-outcoupling efficiency is enhanced.

The doped region 1a may be formed across the entire surface of the first substrate 1 (support substrate 9), or as illustrated in FIG. 5, may be formed in a region overlapping with the organic light-emitting laminate 3 in a plan view. When the doped region 1a is formed across the entire surface of the first substrate 1, the doped region 1a can be easily formed. When the doped region 1a is formed in a region of the first substrate 1 overlapping with the organic light-emitting laminate 3, the light-outcoupling efficiency can be efficiently enhanced. Further, it is also preferred that the doped region 1a do not extend to the enclosing side wall 8a. In this case, the support substrate 9 can be bonded at an undoped part thereof, and hence the bonding performance between the support substrate 9 and the enclosing substrate 8 can be enhanced.

The surface of the first substrate 1 on the doped region 1a side is preferred to be a flat surface. Accordingly, the organic light-emitting laminate 3 can be formed by stacking without short-circuit failure. As a matter of course, a planarizing layer for providing a planarized surface over the surface having the doped region 1a formed therein can be formed on the surface of the first substrate 1. The planarizing layer can be formed of a resin layer.

Incidentally, when the substrate having the doped region 1a is used, the organic EL element can have a structure in which a scattering layer is not formed between the substrate and the electrode. When the scattering layer is absent, a step of forming the scattering layer is unnecessary, and formation of a layer for assisting the scattering layer such as a planarizing layer is also unnecessary, which simplifies the manufacture. As a matter of course, the organic EL element may include the scattering layer. When the scattering layer is present, the action of reducing an effect caused by the refractive index difference between the substrate and the organic layer and the light scattering action can be highly obtained, and thus the light-outcoupling efficiency can be improved.

FIG. 6 shows another example of the organic EL element. The same components as the examples described above are denoted by the same reference signs, and descriptions thereof are omitted herein. The organic EL element of FIG. 6 differs from the organic EL element of FIG. 5 in that the first substrate 1 has the uneven structure 10, and a resin layer 4 is formed on the surface of the first substrate 1. The remaining configurations may be similar to those of FIG. 5.

The organic EL element of FIG. 6 is a bottom-emission element similar to the organic EL element of FIG. 5. The first substrate 1 serves as the support substrate 9. The second substrate 2 serves as the enclosing substrate 8. Light is extracted through the first substrate 1.

In FIG. 6, the first substrate 1 serves as the support substrate 9, and hence the organic light-emitting laminate 3 is formed by stacking layers on the surface of the first substrate 1. That is, on the first substrate 1, the first electrode 5, the organic light-emitting layer 6, and the second electrode 7 are stacked in the stated order. The enclosing side wall 8a extends from the outer peripheral portion of the second substrate 2 that serves as the enclosing substrate 8.

Also in the bottom-emission organic EL element, the first substrate 1 includes the doped region 1a. Accordingly, the light-outcoupling efficiency is enhanced. Further, it is preferred that, as illustrated in FIG. 6, the uneven structure 10 be formed on the surface of the first substrate 1. Accordingly, the light-outcoupling efficiency is further enhanced.

When the first substrate 1 has the uneven structure 10 in the bottom-emission structure, the resin layer 4 is preferred to be formed between the first substrate 1 and the organic light-emitting laminate 3. When the first substrate 1 serves as the support substrate 9 and the first substrate 1 has the uneven structure 10, in a case where the layers constituting the organic light-emitting laminate 3 are directly formed on the uneven structure 10, the organic light-emitting laminate 3 may not be satisfactorily formed due to the uneven shape of the surface of the uneven structure 10. Stacking of layers with disconnection by steps or the like may cause short-circuit failure or light emission failure. In view of this, the resin layer 4 is formed between the first substrate 1 and the organic light-emitting laminate 3 so that the resin layer 4 provides a planarized surface over the uneven surface of the uneven structure 10. Then, the organic light-emitting laminate 3 can be formed on the planarized surface. Therefore, a highly-reliable element which does not suffer from short-circuit failure and light emission failure can be obtained.

The uneven structure 10 may have the uneven shape described in the above-mentioned top-emission structure. That is, for example, the recessed portions 11 having a triangular shape in cross section may be employed. Alternatively, for example, the recessed portions 11 having a hemispherical shape or a semi-ellipsoidal shape may be employed. In FIG. 6, the curved recessed portions 11 are illustrated.

It is preferred that the uneven structure 10 do not exist at the enclosing side wall 8a. It is preferred that the resin layer 4 do not extend to the enclosing side wall 8a. In FIG. 6, the resin layer 4 is formed so as to cover the uneven structure 10. When the resin layer 4 extends outside the enclosed part, intrusion of moisture may easily occur. Therefore, the resin layer 4 is preferred to be formed within the enclosed region. Further, when the uneven structure 10 extends to the enclosing side wall 8a without being covered with the resin layer 4, the electrode lead-out portion 14 is directly formed on the uneven surface, and thus energization performance is likely to decrease.

The resin layer 4 is preferred to contain fine particles having a light scattering property. Accordingly, the fine particles provide a light scattering function, and hence the light-outcoupling efficiency can be further improved.

The fine particles are not particularly limited as long as the fine particles have a light scattering property, but, for example, inorganic fine particles can be used. In particular, silica fine particles are preferred. With use of the silica fine particles, the light scattering performance can be efficiently enhanced.

The average particle diameter of the fine particles is not particularly limited, but is preferred to be 100 nm or more and 1,000 nm or less. Accordingly, the light scattering action can be enhanced.

The fine particles having the light scattering property are preferred to be hollow fine particles having voids therein. Accordingly, the refractive index difference between the substrate and the organic layer can be reduced, and hence the light-outcoupling efficiency can be further improved. As the fine particles, for example, inorganic fine particles having a hollow structure can be used. In particular, hollow silica fine particles are preferred. With use of the hollow silica fine particles, the light-outcoupling efficiency can be efficiently enhanced.

Note that, the preferable configurations of the resin layer 4 (containing fine particles and containing hollow fine particles) may be also available in a case where the resin layer is provided in the filled sealing structure in the top-emission structures of FIG. 1 to FIG. 4. At this time, in the example of FIG. 4, the protruding portions 12 are in contact with the organic light-emitting laminate 3, and hence the gaps formed by the recessed portions 11 may be filled with the resin layer.

In the organic EL element of FIG. 6, as in the example of FIG. 4, the protruding portions 12 may be in contact with the first electrode 5 of the organic light-emitting laminate 3. In this case, the protruding portions 12 are in contact with the organic light-emitting laminate 3, and hence the gaps formed by the recessed portions 11 may be filled with the resin layer 4.

Incidentally, FIG. 5 and FIG. 6 relate to the bottom-emission structure, and hence the structure for leading out the electrode is different from that in the case of FIG. 1 to FIG. 4. That is, the arrangement of the first electrode lead-out portion 14a and the second electrode lead-out portion 14b is different. However, the pattern of the electrode lead-out structure is only required to be considered by exchanging the first electrode 5 and the second electrode 7 with each other, and hence the electrode lead-out structure is easily understood.

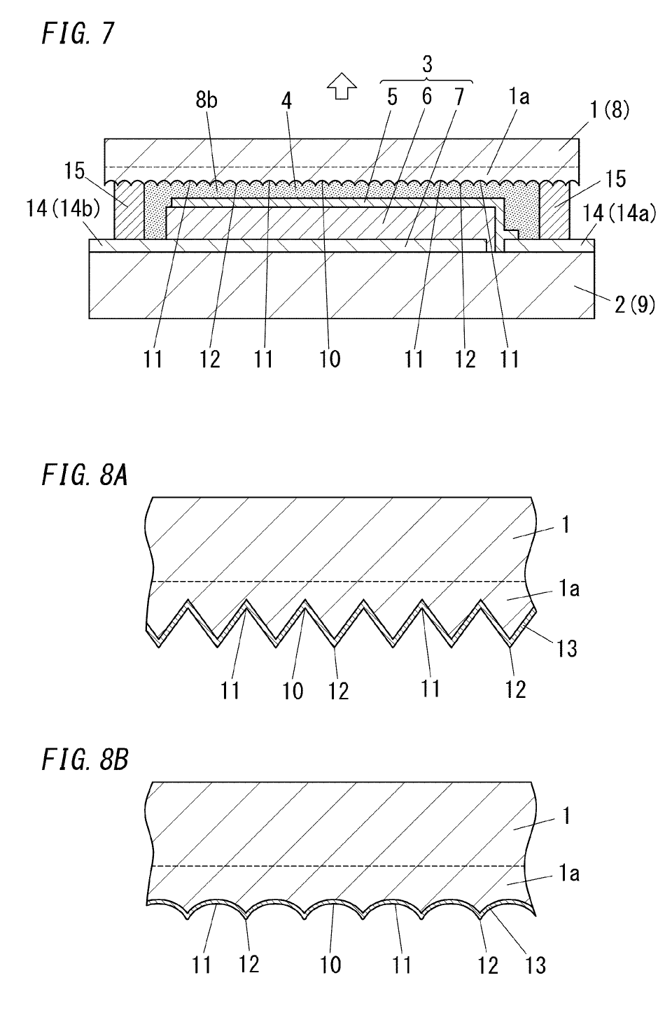

FIG. 7 shows another example of the organic EL element. The same components as the examples described above are denoted by the same reference sings, and descriptions thereof are omitted herein.

The organic EL element of FIG. 7 is a top-emission element, similarly to the element of FIG. 1. The first substrate 1 serves as the enclosing substrate 8. The second substrate 2 serves as the support substrate 9. Light is extracted through the first substrate 1.

In the organic EL element of FIG. 7, the resin layer 4 is formed between the first substrate 1 and the organic light-emitting laminate 3. The doped region 1a and the uneven structure 10 are formed across the entire surface of the first substrate 1 on the organic light-emitting laminate 3 side. The recessed portion 11 has a curved shape.

In FIG. 7, the first substrate 1 (enclosing substrate 8) is formed into a flat-plate shape, and the side wall for enclosing is formed by a spacer 15. The spacer 15 is made of a glass material, a resin material, or the like.

Presence of the resin layer 4 suppresses the deformation of the first substrate 1 (enclosing substrate 8), thereby being capable of suppressing occurrence of short-circuit failure and light emission failure caused when the first substrate 1 presses the organic light-emitting laminate 3.

The resin layer 4 may be made of a material similar to that described in the example of FIG. 6. The resin layer 4 is preferred to contain fine particles having a light scattering property. The fine particles are preferred to be hollow fine particles having voids therein.

In the example of FIG. 7, the spacer 15 is placed on the support substrate 9 having the organic light-emitting laminate 3 formed thereon, so as to surround the outer peripheral sides of the organic light-emitting laminate 3. Then, a space surrounded by the spacer 15 is filled with a resin material, and the enclosing substrate 8 is bonded to the spacer 15, thereby being capable of enclosing the organic light-emitting laminate 3. The spacer 15 serves as a dam material, and the resin layer 4 serves as a filling material. In this example, a so-called dam-and-fill organic EL element can be formed.

As described above, according to one preferable aspect, the resin layer 4 is formed between the first substrate 1 and the organic light-emitting laminate 3. Accordingly, when the organic light-emitting laminate 3 is enclosed by the first substrate 1, the deformation of the first substrate 1 can be suppressed and thus it is possible to enhance the robustness, and when the organic light-emitting laminate 3 is supported by the first substrate 1, the organic light-emitting laminate 3 can be satisfactorily formed by stacking. Therefore, the reliability can be improved.

FIGS. 8A and 8B are illustrations of preferable configurations of the first substrate 1. Those configurations of the first substrate 1 may be used in any of the organic EL elements of FIG. 1 to FIG. 7. The same components are denoted by the same reference signs. Note that, the illustrations relate to a top-emission structure, and hence the uneven structure 10 is formed on the lower surface. In contrast, the uneven structure 10 may be formed on the upper surface, and in other words the above uneven structure 10 can be used in the bottom-emission structure.

The first substrate 1 is preferred to include, on the surface on the doped region 1a side, a coat layer 13 which is light-transmissive and light-reflective. Accordingly, the coat layer 13 can enhance the light scattering performance and further suppress the total reflection, and hence the light-outcoupling efficiency can be further improved.

In FIGS. 8A and 8D, the first substrate 1 includes the coat layer 13 being light-transmissive and light-reflective, on the surface on the doped region 1a side. Accordingly, the coat layer 13 can further suppress the total reflection, and hence the light-outcoupling efficiency can be further improved.

The coat layer 13 functions more effectively when the first substrate 1 has the uneven structure 10. The reason is as follows. In the uneven structure 10, the recesses and protrusions on the surface cause light to scatter so that light is extracted to the outside. With use of the coat layer 13, the scattering action of the uneven structure 10 can be enhanced. As a matter of course, the coat layer 13 may be formed in a case where the first substrate 1 has a flat surface.

FIG. 8A shows an example in which the coat layer 13 is formed on the uneven structure 10 having a triangular shape in cross section as illustrated in FIG. 2. As illustrated in FIG. 8A, the coat layer 13 is preferred to be formed along the uneven shape of the uneven structure 10. If the coat layer 13 does not reflect the recesses and protrusions, there is a fear in that the light scattering function may not be sufficiently obtained.

FIG. 8B shows an example in which the coat layer 13 is formed on the uneven structure 10 having the curved recessed portions 11 as illustrated in FIG. 3, FIG. 4, FIG. 6, and FIG. 7. Also in this example, the coat layer 13 is formed along the recesses and protrusions. In this example, the coat layer 13 provides the rounded leading end of the protruding portion 12. When the leading end of the protruding portion 12 is rounded, in a case where the first substrate 1 is in contact with the organic light-emitting laminate 3 as in FIG. 4, damage on the organic light-emitting laminate 3 can be suppressed.

Note that, when the coat layer 13 is provided in the example of FIG. 4, the protruding portions 12 of the first substrate 1 are in contact with the organic light-emitting laminate 3 at the coat layer 13. The same holds true also in the case where the protruding portions 12 are in contact with the organic light-emitting laminate 3 in the bottom-emission structure.

The coat layer 13 is preferred to be formed of a metal thin film. Accordingly, the total reflection can be further suppressed, and hence the light-outcoupling efficiency can be further improved.

The metal thin film may be selected from thin films of silver, gold, copper, aluminum, and the like, alloy thin films of those metals, and alloy thin films of those metals and other metals. Among them, a thin film containing silver or aluminum is preferred. Accordingly, the light-outcoupling efficiency can be further improved.

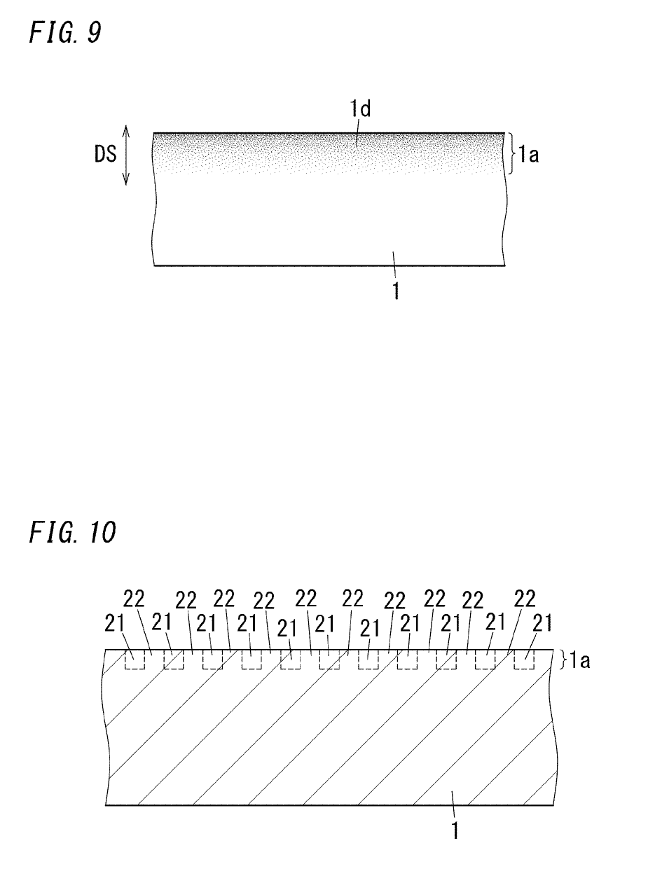

FIG. 9 shows a preferable example of the first substrate 1. This configuration of the first substrate 1 may be used in any of the organic EL elements of FIG. 1 to FIG. 7. The same components are denoted by the same reference signs. Note that, the illustration relates to the bottom-emission structure, and hence the doped region 1a is illustrated as being provided on the upper side. In contrast, the doped region 1a may be provided on the lower side, and in other words the above doped region 1a can be used in the top-emission structure. Note that, in FIG. 9, the organic light-emitting laminate 3 is omitted, but, for example, in the bottom-emission structure, the organic light-emitting laminate 3 is formed on the first substrate 1 (support substrate 9).

The doped region 1a is preferred to have a concentration distribution in a thickness direction of the first substrate 1. Accordingly, the concentration of the dopant varies in the thickness direction, and hence the reduction in light-outcoupling efficiency due to reflection can be suppressed. In the present description, the concentration distribution means that concentration is not uniform. The concentration distribution may mean that the concentration of the dopant varies in the thickness direction. The thickness direction of the first substrate 1 is the same as the direction of the outline arrow indicated as the light exiting direction in FIG. 1 to FIG. 7. In FIG. 9, the thickness direction of the first substrate 1 is indicated by the two-way arrow DS. In the concentration distribution, the concentration is preferred to vary gradually. Gradual variation of concentration leads to smooth variation of the refractive index, and hence the reduction in light-outcoupling efficiency due to reflection may be further suppressed.

In the doped region 1a, the concentration distribution in the thickness direction of the first substrate 1 may include a case where the concentration becomes higher toward the organic light-emitting laminate 3, and a case where the concentration becomes higher toward the opposite side from the organic light-emitting laminate 3 (substrate internal side). The concentration distribution in the thickness direction of the first substrate 1 is preferred to show that a concentration becomes higher toward the organic light-emitting laminate 3. Accordingly, the variation of the refractive index of the first substrate 1 becomes greater toward the organic light-emitting laminate 3, and hence the reflection can be further suppressed, thereby being capable of improving the light-outcoupling efficiency. In the concentration distribution, the dopant concentration is preferred to become higher toward the organic light-emitting laminate 3. In the concentration distribution in the thickness direction of the first substrate 1, the dopant concentration is preferred to become lower toward the internal side of the first substrate 1. In the concentration distribution, the concentration may vary in a stepwise manner from a higher concentration to a lower concentration, or may continuously vary from a higher concentration to a lower concentration so that there are no boundary lines between concentration regions.

In the first substrate 1 of FIG. 9, a dopant 1d is schematically represented by dots. The doped region 1a of the first substrate 1 has a concentration distribution in which the concentration of the dopant 1d varies in the thickness direction of the first substrate 1. In FIG. 9, dense dots are illustrated on the upper side corresponding to the side close to the organic light-emitting laminate 3, and sparse dots are illustrated on the lower side corresponding to the substrate internal side. Therefore, the dopant concentration distribution in the thickness direction of the first substrate 1 shows that a concentration becomes higher toward the organic light-emitting laminate 3. Therefore, with this aspect, the reflection can be further suppressed, and the light-outcoupling efficiency can be improved. Note that, in FIG. 9, the outer border of the doped region 1a is understood by the dots of the dopant 1d, and hence the broken line for indicating the outer border of the doped region 1a is omitted. Further, hatching for representing a cross section is also omitted for clear illustration of the dots.

When the doped region 1a has the concentration distribution in the thickness direction of the first substrate 1, the doped region 1a is more preferred to contain a plurality of types of dopants. Accordingly, the concentration distribution of the doped region 1a in the thickness direction can be easily achieved. For example, when a heavy element and a light element are used as the dopants for ion implantation, the heavy-element ion is less likely to reach the deeper side of the substrate, whereas the light-element ion is likely to reach the deeper side of the substrate. Therefore, the dopant concentration can be easily varied in the thickness direction. The number of types of dopants is not particularly limited and may be three or more, but is more preferred to be two. The doped region 1a can be produced easier as the number of types of the dopant is smaller. Note that, when the number of types of the dopant is one, the concentration distribution in the thickness direction can be achieved by adjusting the implantation depth of the dopant by changing the output for doping, for example.

When the doped region 1a has the concentration distribution in the thickness direction of the first substrate 1, the thickness of the concentration distribution is preferred to be within a range of from 0.1 μm to 1 μm. Accordingly, the concentration distribution can be easily formed by ion implantation. Particularly when the plurality of types of dopants are used, the formation of the concentration distribution is facilitated. The upper limit of the thickness range of the concentration distribution may be equal to the thickness of the doped region 1a.

FIG. 10 shows a preferable example of the first substrate 1. This configuration of the first substrate 1 may be used also in any of the organic EL elements of FIG. 1 to FIG. 7. The same components are denoted by the same reference signs. Note that, the illustration relates to the bottom-emission structure, and hence the doped region 1a is illustrated as being provided on the upper side. In contrast, the doped region 1a may be provided on the lower side, and in other words the doped region 1a may be used in the top-emission structure. Note that, in FIG. 10, the organic light-emitting laminate 3 is omitted, but, for example, in the bottom-emission structure, the organic light-emitting laminate 3 is formed on the first substrate 1 (support substrate 9).

According to one preferable aspect, the doped region 1a has a planar concentration distribution. Accordingly, in the doped region 1a, regions having different refractive indexes are arranged in plane, and hence the reflection can be suppressed and the light-outcoupling efficiency can be improved. The planar concentration distribution may show a pattern. When the doped region 1a has a planar concentration distribution, in a plan view of the first substrate 1, the concentration of the dopant may vary depending on the position.

The planar concentration distribution is preferred to include a first concentration region 21 and a second concentration region 22 having different dopant concentrations. Accordingly, a pattern excellent in light-outcoupling efficiency may be easily formed. The first concentration region 21 is defined as a region having a higher dopant concentration than the second concentration region 22. According to one preferable aspect, the planar concentration region includes the first concentration region 21 defining a dopant containing region containing the dopant, and the second concentration region 22 defining a dopant non-containing region not containing the dopant. Alternatively, when both of the first concentration region 21 and the second concentration region 22 contain the dopant, the first concentration region 21 may define a high concentration region, and the second concentration region 22 may define a low concentration region. As compared to the combination of the high concentration region and the low concentration region, the combination of the dopant containing region and the dopant non-containing region has an advantage in that the concentration difference is larger, and therefore the higher light-outcoupling efficiency may be obtained. Further, when the regions are formed based on whether to contain the dopant, the formation of the doped region 1a having a planar concentration distribution is facilitated. Note that, the planar concentration distribution may be achieved by three or more regions having different dopant concentrations.

The first substrate 1 of FIG. 10 has the first concentration region 21 and the second concentration region 22 whose dopant concentration is lower than that of the first concentration region 21. In FIG. 10, the outer border of the first concentration region 21 is indicated by the broken line. The second concentration region 22 has a lower dopant concentration than the first concentration region 21, and may not contain the dopant, and hence the second concentration region 22 is illustrated as being coupled with the main body of the first substrate 1 (part other than the doped region 1a) without a boundary. As described above, when the concentration distribution is planar, in sectional view as in FIG. 10, the first concentration region 21 and the second concentration region 22 may be arranged side by side in a direction parallel to the surface of the first substrate 1.

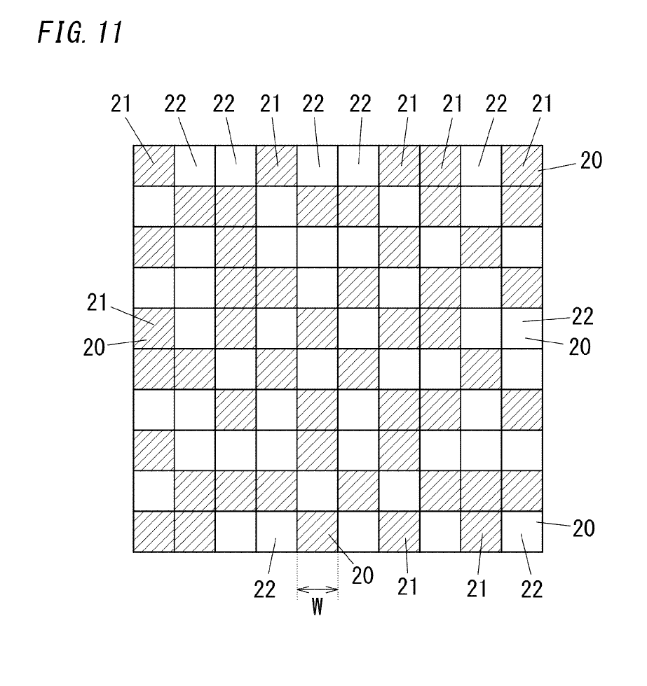

FIG. 11 shows an example of the planar concentration distribution pattern formed in the first substrate 1. The planar concentration distribution is preferred to be a distribution showing a matrix of sections 20 each corresponding to the first concentration region 21 or the second concentration region 22. Accordingly, the effect of suppressing the reflection is enhanced, and hence the light-outcoupling efficiency can be enhanced. In FIG. 11, any one of the first concentration region 21 and the second concentration region 22 is assigned to each of the plurality of sections 20. In FIG. 11, the first concentration region 21 is illustrated as a hatched region, and the second concentration region 22 is illustrated as a blank region. Note that, for easy understanding of the pattern, the boundary of the sections 20 is indicated by the solid line, but in the actual case, such a boundary may not exist between continuous regions having the same concentration.

The pattern of the matrix of the sections 20 is preferred to be a grid pattern. Accordingly, the first concentration regions 21 and the second concentration regions 22 are easily arranged uniformly, and hence the light-outcoupling efficiency can be enhanced more uniformly in a plane. FIG. 11 is an illustration of a case of the quadrangular grid. The quadrangular grid may be a pattern obtained by arranging a plurality of quadrangles having the same shape continuously side by side vertically and laterally. The quadrangle forming the quadrangular grid may be a rectangle (including a square).

According to one preferable aspect, the first concentration regions 21 and the second concentration regions 22 are arranged so that they are randomly assigned to the grid-patterned sections 20. Accordingly, the light-outcoupling efficiency is enhanced more uniformly in a plane. Further, according to another preferable aspect, the first concentration regions 21 and the second concentration regions 22 are alternately arranged. In this case, the concentration region pattern may be a gingham pattern.

As illustrated in FIG. 11, a plurality of first concentration regions 21 are formed, and a plurality of second concentration regions 22 are formed. When the first concentration regions 21 are continuously arranged in the sections 20, the first concentration regions 21 are coupled to each other to form a larger concentration region. A region formed by the coupled first concentration regions 21 is defined as a first concentration portion. When the second concentration regions 22 are continuously arranged in the sections 20, the second concentration regions 22 are coupled to each other to form a larger concentration region. A region formed by the continuous second concentration regions 22 is defined as a second concentration portion.

In the planar concentration distribution, it is preferred that an area ratio of the first concentration regions 21 in a unit region in a plan view be substantially the same in respective unit regions. When such a concentration distribution is realized, the light-outcoupling efficiency can be efficiently improved. Similarly, in the planar concentration distribution, it is preferred that an area ratio of the second concentration regions 22 in a unit region in a plan view be substantially the same in respective unit regions. In this case, the unit region for calculating the area ratio is defined as a region constituted by a plurality of sections 20 which are arranged in plane. For example, in FIG. 11, a total of 100 (10×10) sections 20 are illustrated, and such a region of 100 sections can be regarded as a unit region. In FIG. 11, the first concentration regions 21 the number of which is equal to the number of sections of 50 are provided. Therefore, another unit region which is the same in the number of sections and the area as that unit region may include the first concentration regions 21 the number of which is equal to the number of sections of about 50 (e.g., 45 to 55 or 48 to 52). The unit region is not limited to a region of 100 sections, and can have a size corresponding to an appropriate number of sections. For example, the number of sections may be 1,000, 10,000, 100,000, or more. The area ratios of the first concentration regions 21 may slightly differ depending on how the regions are taken, but these area ratios are preferred to be substantially the same. For example, a difference between an upper limit and an average of the area ratio and a difference between a lower limit and the average of the area ratio are preferably 10% or less of the average, more preferably 5% or less, further preferably 3% or less, still further preferably 1% or less. When the area ratio is more equalized, the light-outcoupling efficiency can be enhanced more uniformly in a plane. The area ratio of the first concentration regions 21 in the unit region is not particularly limited, but can be set, for example, within a range of from 20% to 80%, preferably within a range of from 30% to 70%, more preferably within a range of from 40% to 60%. The second concentration region 22 is, in FIG. 11, a region other than the first concentration region 21, and may be set similarly to the above. When the unit regions have substantially the same area ratio of the regions having the same concentration, the viewing angle dependence may also be reduced.

As illustrated in FIG. 11, this concentration distribution is formed by arranging one or more first concentration regions 21 and one or more second concentration regions 22 so that one of the first concentration region 21 and the second concentration region 22 is allocated to each of sections 20 of the matrix formed by arraying a plurality of squares vertically and horizontally to show a grid (row-column form). The respective sections 20 are formed to have the same area. The allocation may be regular or irregular. FIG. 11 shows the example in which the concentration regions are allocated randomly. The plurality of first concentration regions 21 may have substantially the same concentration. The plurality of second concentration regions 22 may have substantially the same concentration.

The coupling number of first concentration regions 21 or second concentration regions 22 is not particularly limited, but increase in the coupling number may cause the light-outcoupling efficiency to be non-uniform. Therefore, for example, the coupling number can be set as appropriate to 100 or less, 20 or less, 10 or less, or the like. The following design rule may be provided. Specifically, when three or more or two or more first concentration regions 21 or second concentration regions 22 are successively continued in the same direction, the next region may be a different region (i.e., the second concentration region in the case of the first concentration region, and the first concentration region in the case of the second concentration region). According to this rule, the light-outcoupling efficiency is enhanced more uniformly.

A width w of the section 20 can be set to, for example, 0.1 μm to 100 μm, but the width w is not limited thereto. In a case of the quadrangular grid pattern formed of squares, the width w of the section 20 is one side of the square. The width w of the section 20 may be 0.4 μm to 10 μm. The width w of the section 20 can be regarded as a diameter representing the size of the first concentration region 21 or the second concentration region 22.

The planar concentration distribution may reflect a diffraction structure. Accordingly, the light-outcoupling efficiency can be enhanced.

The planar concentration distribution may reflect a boundary diffraction structure. The boundary diffraction structure may be a structure in which the first concentration regions 21 and the second concentration regions 22 are arranged randomly. In the boundary diffraction structure, it is preferred that, under the principle that the number of the same type of concentration regions continuously arrayed in the same direction is not equal to or more than a predetermined number, the first concentration regions 21 and the second concentration regions 22 be arranged in the sections 20 irregularly. The predetermined number of the same type of concentration regions not continuously arrayed in the same direction is preferably 10 or less, more preferably 8 or less, further preferably 5 or less, still further preferably 4 or less.

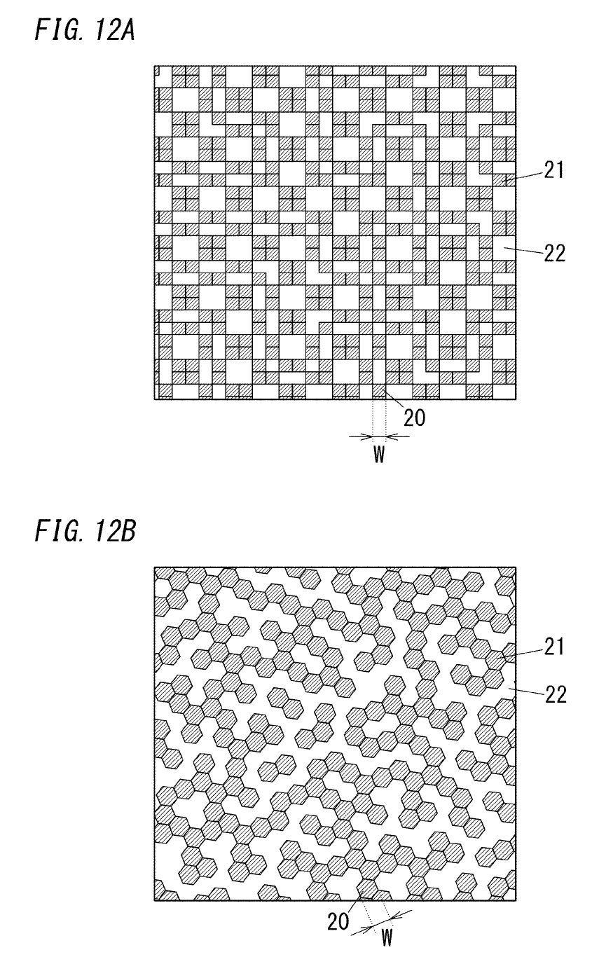

FIGS. 12A and 12B show examples of the planar concentration distribution pattern. Those concentration distributions are controlled so that the arrangement of the first concentration regions 21 and the second concentration regions 22 is random and the number of regions which have the same concentration and are arrayed in the same direction is not equal to or more than the predetermined number. Similarly to the example of FIG. 11, the first concentration region 21 is illustrated as a hatched region, and the second concentration region 22 is illustrated as a blank region. Note that, the boundary lines between the continuous second concentration regions 22 are omitted. The patterns of FIGS. 12A and 12B are examples of the boundary diffraction structure.

FIG. 12A shows a pattern of a case of the quadrangular grid. In FIG. 12A, three or more regions having the same concentration are not arrayed in the same direction. Therefore, the light-outcoupling efficiency is uniformly enhanced.

FIG. 12B shows a case of the hexagonal grid. As illustrated in FIG. 12B, the pattern of the grid-shaped sections 20 may have a hexagonal shape. The hexagonal shape is further preferred to be a regular hexagonal shape. In this case, a honeycomb grid (hexagonal grid) in which a plurality of hexagonal shapes are spread in a filled structure is obtained. In the hexagonal grid, a distance between two opposing sides of the hexagonal shape corresponds to the width w of the grid. In FIG. 12B, four or more regions having the same concentration are not arrayed in the same direction. Therefore, the light-outcoupling efficiency is uniformly enhanced.

Note that, in the first substrate 1, the planar concentration distribution and the concentration distribution in the thickness direction may coexist. Accordingly, the light-outcoupling efficiency can be enhanced. Further, the first substrate 1 may have both of the concentration distribution and the uneven structure 10. Accordingly, the light-outcoupling efficiency can be enhanced.

The method of manufacturing the above-mentioned organic EL element is described.

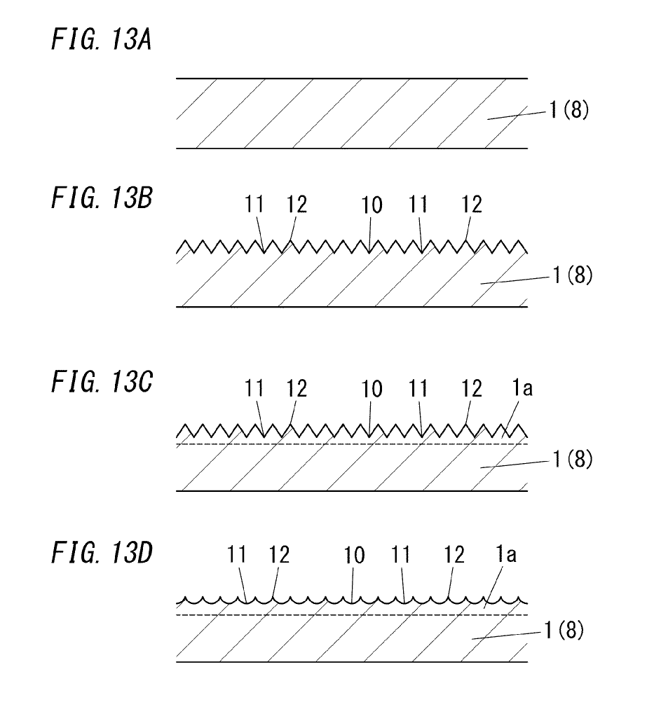

FIGS. 13A to 13D are illustrations of the processing of the first substrate 1 in manufacturing the organic EL element.

The manufacturing the organic EL element is preferred to include an implanting step and a diffusing step. The implanting step is a step of implanting, into the surface of the first substrate 1, a dopant for causing change in the refractive index of the first substrate 1 to enhance the light-outcoupling efficiency. The diffusing step is a step of diffusing an implanted dopant. According to those implanting step and diffusing step, the doped region 1a can be satisfactorily and easily formed in the surface of the first substrate 1. Therefore, the light-outcoupling efficiency can be easily and efficiently enhanced by implanting the dopant, and hence an organic EL element having high light-outcoupling efficiency can be easily manufactured.

When the first substrate 1 serves as the enclosing substrate 8, the processing of the first substrate 1 can be performed on a substrate material before the organic EL element is enclosed. When the first substrate 1 serves as the support substrate 9, the processing of the first substrate 1 can be performed on a substrate material before the organic EL element is formed by stacking.

The manufacturing the organic EL element is further preferred to include a roughening step. The roughening step is a step of roughening the surface of the first substrate 1. With the roughening step, the surface of the first substrate 1 becomes a roughened surface, and the roughened surface serves as the uneven structure 10. This uneven structure 10 can suppress the total reflection, and hence the light-outcoupling efficiency can be further improved. The roughening step is preferred to be a step of roughening the surface of the first substrate 1 by blasting. Accordingly, a roughened surface offering a high light-outcoupling efficiency can be easily formed.

The manufacturing the organic EL element is further preferred to include a melting step. The melting step is a step of melting the roughened surface of the first substrate 1 along the recesses and protrusions of the roughened surface by heating the roughened surface. Melting the roughened surface along the recesses and protrusions may mean slightly melting the surface of the first substrate 1 so as not to collapse the recesses and protrusions of the uneven structure 10. With the melting step, the roughened surface can be slightly smoothened, to thereby form the recessed portion 11 formed on the roughened surface into a curved surface. Forming the recessed portion 11 into the curved surface makes it easier to obtain the lens action, and hence the light-outcoupling efficiency can be enhanced more efficiently.

In the manufacturing the organic EL element, the implanting step is preferred to be performed after the roughening step. Accordingly, a structure having a high light-outcoupling efficiency can be efficiently and easily formed on the surface of the first substrate 1, and hence an element having a high light-outcoupling efficiency can be manufactured more easily. As a matter of course, the roughening step may be performed after the implanting step, but in this case, the implanted doped region 1a may be partially removed by roughening, and therefore the manufacturing efficiency is likely to be degraded. Therefore, performing the implanting step after the roughening step is more advantageous.

In the manufacturing the organic EL element, the melting step and the diffusing step are preferred to be simultaneously performed. Since the diffusing step is considered a step of diffusing the dopant implanted into the surface of the first substrate 1, the diffusing step can be easily performed by heating. On the other hand, since the melting step is considered a step of deforming the roughened surface, the melting step can be performed by heating the surface of the first substrate 1. Therefore, when the melting step and the diffusing step are simultaneously performed, the dopant can be diffused and the roughened surface can be deformed through one-time heating of the substrate. Therefore, the organic EL element can be efficiently manufactured.

In processing of the first substrate 1, first, as illustrated in FIG. 13A, the first substrate 1 is prepared. Next, the surface of the first substrate 1 is roughened by blasting, which corresponds to the roughening step. As illustrated in FIG. 13B, the surface of the first substrate 1 is roughened by blasting, to thereby form the uneven structure 10. Blasting can be performed by using appropriate blast particles. Sand blasting is preferred, which facilitates the roughening. The uneven structure 10 formed at this time may have an uneven shape formed by the recessed portions 11 and the protruding portions 12, which have a triangular shape in cross section.

Next, the implanting step is performed. As illustrated in FIG. 13C, with the implanting step, the surface of the first substrate 1 is doped with the dopant, and the doped region 1a is formed. When the dopant is ions, the doped region 1a is formed by ion irradiation. When the dopant is particles, the particles are implanted to form the doped region 1a. Note that, in FIG. 13C, a state where the doped region 1a is formed is illustrated, but in the implanting step, the doped region 1a may not be formed in the thickness direction, and the dopant may only exist on the surface of the first substrate 1. This is because, with the next diffusing step and melting step, the dopant can be caused to enter the first substrate 1, to thereby form the doped region 1a. In this case, particles serving as the dopant may be disposed on the surface of the first substrate 1 by spraying the particles.

In forming the doped region 1a having the concentration distribution in the thickness direction, to achieve the concentration distribution in the thickness direction, the dopant may be implanted so that the concentration varies in the thickness direction. The concentration distribution in the thickness direction can be easily achieved by implanting a plurality of types of dopants. The plurality of types of dopants may be implanted simultaneously, or may be implanted separately, but simultaneous implantation facilitates the manufacture. For example, when a heavy-element dopant and a light-element dopant are simultaneously implanted, a larger amount of heavy element is present on the surface side, and a larger amount of light element is present further on the internal side. Therefore, the concentration distribution in the thickness direction is formed in the doped region 1a. Note that, in forming the concentration distribution in the thickness direction with one type of dopant, the implantation energy may be changed to enable formation of the concentration distribution in the thickness direction. When the energy during implantation is weak, a larger amount of dopant is present on the surface side, and when the energy during implantation is strong, a larger amount of dopant is present further on the internal side.

Further, in forming the doped region 1a having the planar concentration distribution, the dopant may be implanted into a pattern, to thereby form the planar concentration distribution. The implantation pattern may be the pattern for enhancing the light-outcoupling efficiency as described above. As a pattern implantation method, there may be given a method of using a mask, a drawing method, and the like. In the method of using the mask, a part to be a non-implanting part may be covered with a mask to prevent implantation of the dopant, and the dopant may be implanted into a part not covered with the mask. In the drawing method, the dopant may be discharged along a pattern of a part to be implanted to draw the pattern, to thereby implant the dopant. The planar concentration distribution can be easily manufactured when a combination of the first concentration region 21 and the second concentration region 22 is a combination of the dopant containing region and the dopant non-containing region. Note that, through adjustment of the output or implantation range or the like, the combination of the first concentration region 21 and the second concentration region 22 can be a combination of the high concentration region and the low concentration region.

Incidentally, when the first substrate 1 serves as the enclosing substrate 8, the accommodating recessed portion 8b can be formed in advance. Then, the uneven structure 10 can be formed on the bottom surface of the accommodating recessed portion 8b, and the dopant can be implanted therein. It is preferred that, by blasting, the surface of the first substrate 1 be engraved to form the accommodating recessed portion 8b, and simultaneously the surface of the accommodating recessed portion 8b be roughened. Accordingly, the accommodating recessed portion 8b can be simultaneously formed and roughened (the uneven structure 10 can be formed), and hence the substrate can be processed efficiently.

Next, the surface of the first substrate 1 is heated. This heating corresponds to the diffusing step and the melting step. In this example, the diffusing step and the melting step are simultaneously performed. With those steps, the surface of the first substrate 1 is slightly melted so that the material flows to the extent that the recesses and protrusions do not collapse, and hence the dopant is diffused along with the melting. When the dopant is diffused by melting, the dopant can be diffused in a wider range. When the dopant is diffused by melting, the thickness of the doped region 1a can be increased. Further, as illustrated in FIG. 13D, with those steps, the surface of the recessed portion 11 may be rounded to obtain a curved surface.

The first substrate 1 produced as described above can be used as a substrate material for the organic EL element. In FIGS. 13A to 13D, the first substrate 1 can be used as the enclosing substrate 8.

On the second substrate 2 that serves as the support substrate 9, the organic light-emitting laminate 3 is formed in another step. The organic light-emitting laminate 3 can be formed by sequentially stacking the layers constituting the organic light-emitting laminate 3 on the support substrate 9. This corresponds to an organic light-emitting laminate forming step. As the stacking process, appropriate methods such as vapor deposition, sputtering, and coating can be used.

Then, the first substrate 1 that serves as the enclosing substrate 8 is placed opposite a side of the second substrate 2 on which the organic light-emitting laminate 3 is formed, and then the first substrate 1 and the second substrate 2 are bonded to each other. At this time, the surface of the first substrate 1 having the doped region 1a formed therein is directed opposite the second substrate 2 that serves as the support substrate 9, and then the first substrate 1 and the second substrate 2 are bonded to each other. The accommodating recessed portion 8b may be formed in advance in the first substrate 1 (enclosing substrate 8). Alternatively, a flat-plate first substrate 1 (enclosing substrate 8) may be used, and the organic light-emitting laminate 3 may be enclosed by forming the filled enclosing structure with use of a dam material and a filling material. Accordingly, the organic light-emitting laminate 3 can be enclosed.

The first substrate 1 illustrated in FIG. 13D can be used to manufacture the organic EL elements of FIG. 3, FIG. 4, and FIG. 7. As a matter of course, when the first substrate 1 in the state of FIG. 13C is used, the first substrate 1 can be used to manufacture the organic EL element illustrated in FIG. 2. With the substrate material of FIG. 13D, the top-emission organic EL element can be satisfactorily manufactured.

It is also preferred to form the coat layer 13 after formation of the structure shown in FIG. 13D. When the coat layer 13 is formed, the first substrate 1 having the coat layer 13 described with reference to FIGS. 8A and 8B can be formed. The coat layer 13 can be made of a material for the coat layer 13 by methods such as vapor deposition, sputtering, and coating. This corresponds to a coat layer forming step.

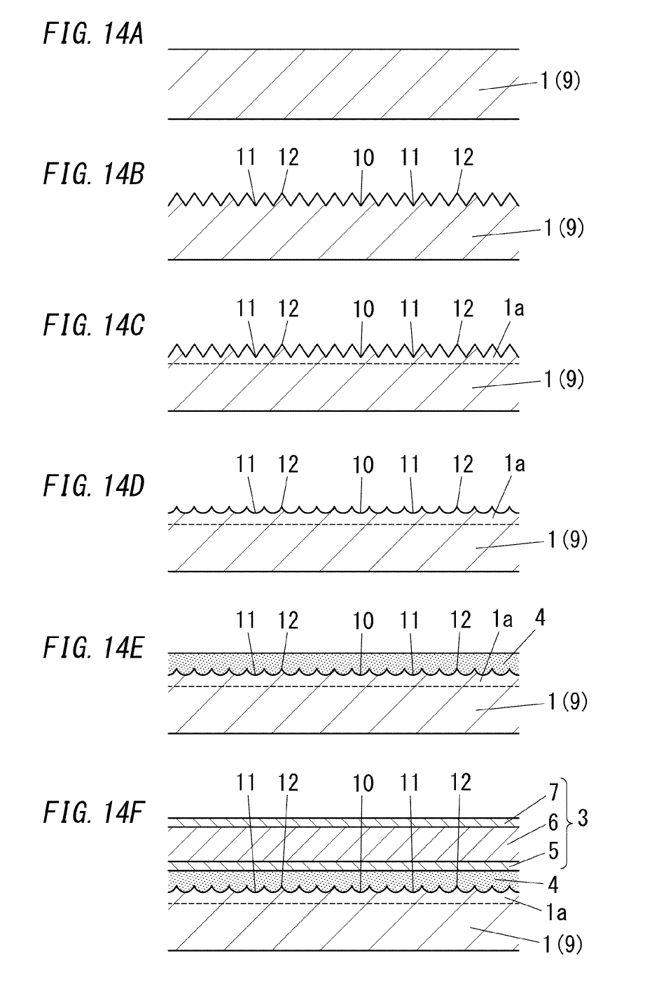

Note that, when the uneven structure 10 is not formed, the surface of the first substrate 1 illustrated in FIG. 13A can be subjected to the implanting step and the diffusing step, to thereby process the substrate. In this case, the surface of the first substrate 1 on the side on which the doped region 1a is formed may be a flat surface. Therefore, the first substrate 1 can be used to manufacture the organic EL element of FIG. 1. FIGS. 14A to 14F are illustrations of processing of the first substrate 1 and formation of the organic light-emitting laminate 3 in manufacturing the organic EL element. In FIGS. 14A to 14F, the bottom-emission organic EL element can be manufactured.

The steps from FIG. 14A to FIG. 14D are the same as the steps from FIG. 13A to FIG. 13D. The first substrate 1 produced as in FIG. 14D can be used as a formation substrate for forming the organic light-emitting laminate 3. As a matter of course, the coat layer 13 may be further formed on the surface of the first substrate 1. The method of forming the coat layer 13 is as described above.

In the bottom-emission organic EL element, it is preferred that the resin layer 4 be formed on the surface of the first substrate 1, and the organic light-emitting laminate 3 be formed on the surface of the resin layer 4. The step of forming the resin layer 4 on the surface of the first substrate 1 corresponds to the resin layer forming step. The step of forming the organic light-emitting laminate 3 corresponds to the organic light-emitting laminate forming step. As illustrated in FIG. 14E, with the resin layer forming step, the uneven surface of the first substrate 1 can be covered with a planarized surface. Therefore, as illustrated in FIG. 14F, the organic light-emitting laminate 3 can be satisfactorily formed without disconnection by steps. As described above, in the method of FIGS. 14A to 14F, the organic light-emitting laminate 3 having a satisfactory lamination structure can be easily formed, and an element having high reliability can be easily manufactured.

The resin layer 4 can be formed by coating the uneven surface of the first substrate 1 with a resin material. With the coating, a flat surface can be easily formed. At this time, when a resin material containing fine particles having a light scattering property is used, the resin layer 4 in which the fine particles having the light scattering property are dispersed can be obtained. At this time, the fine particles may be hollow fine particles.

The organic light-emitting laminate 3 can be formed by sequentially stacking the layers for constituting the organic light-emitting laminate 3. As the stacking process, appropriate methods such as vapor deposition, sputtering, and coating can be used. In this example, the organic light-emitting laminate 3 can be formed by stacking the first electrode 5, the organic light-emitting layer 6, and the second electrode 7 in the stated order. When the organic light-emitting layer 6 includes a plurality of layers, the plurality of layers can be formed sequentially in the order from the layer to be closest to the first electrode 5.

Then, the second substrate 2 that serves as the enclosing substrate 8 is placed opposite the side of the first substrate 1 on which the organic light-emitting laminate 3 is formed, and the first substrate 1 and the second substrate 2 are bonded to each other, thereby being capable of enclosing the organic light-emitting laminate 3. At this time, in the second substrate 2 (enclosing substrate 8), the accommodating recessed portion 8b may be formed in another process. Alternatively, a flat-plate second substrate 2 (enclosing substrate 8) may be used, and the organic light-emitting laminate 3 may be enclosed by forming the filled enclosing structure with use of a dam material and a filling material. As described above, the organic EL element of FIG. 6 may be manufactured. Note that, when the uneven structure 10 and the resin layer 4 are not formed, the organic EL element of FIG. 5 may be manufactured.

### REFERENCE SIGNS LIST

1 First substrate
1a Doped region
2 Second substrate
3 Organic light-emitting laminate

1-20. (canceled)

21. An organic electroluminescence element, comprising:
a first substrate on a light extraction side of the organic electroluminescence element;
a second substrate opposite the first substrate; and
an organic light-emitting laminate between the first substrate and the second substrate,
the first substrate including a doped region in a surface close to the organic light-emitting laminate, the doped region being doped with a dopant for causing change in a refractive index of the first substrate to enhance a light-outcoupling efficiency,
the doped region having a planar concentration distribution, and
the planar concentration distribution showing a matrix of sections each corresponding to a first concentration region or a second concentration region.

22. The organic electroluminescence element according to claim 21, wherein
the doped region is integrated into the first substrate.

23. The organic electroluminescence element according to claim 21, wherein
the doped region has a concentration distribution in a thickness direction of the first substrate.

24. The organic electroluminescence element according to claim 23, wherein
the concentration distribution in the thickness direction of the first substrate shows that a concentration becomes higher towards the organic light-emitting laminate.

25. The organic electroluminescence element according to claim 21, wherein
the first substrate has an uneven structure on a surface on a doped region side of the first substrate.

26. The organic electroluminescence element according to claim 25, wherein
the uneven structure has a plurality of recessed portions curved inwardly of the first substrate.

27. The organic electroluminescence element according to claim 25, wherein
the uneven structure has a protruding portion that is in contact with the organic light-emitting laminate.

28. The organic electroluminescence element according to claim 21, wherein
the first substrate comprises a coat layer on a surface of a doped region side of the first substrate, the coat layer being light-transmissive and light-reflective.

29. The organic electroluminescence element according to claim 28, wherein
the coat layer is formed of a metal thin film.

30. The organic electroluminescence element according to claim 21, further comprising a resin layer between the first substrate and the organic light-emitting laminate.

31. The organic electroluminescence element according to claim 30, wherein
the resin layer contains fine particles having a light scattering property.

32. The organic electroluminescence element according to claim 31, wherein
the fine particles comprise hollow fine particles having voids therein.

33. The organic electroluminescence element according to claim 21, wherein:
the second substrate serves as a support substrate for the organic light-emitting laminate;
the first substrate serves as an enclosing substrate for enclosing the organic light-emitting laminate; and
the organic electroluminescence element has a top-emission structure.

34. The organic electroluminescence element according to claim 21, wherein
the first substrate serves as a support substrate for the organic light-emitting laminate;
the second substrate serves as an enclosing substrate for enclosing the organic light-emitting laminate; and
the organic electroluminescence element has a bottom-emission structure.

35. A method of manufacturing the organic electroluminescence element of claim 21, the method comprising:
implanting, into a surface of a first substrate, a dopant for causing change in a refractive index of the first substrate to enhance a light-outcoupling efficiency; and
diffusing an implanted dopant.

36. The method according to claim 35, further comprising roughening the surface of the first substrate by blasting.

37. The method according to claim 36, further comprising melting a roughened surface of the first substrate along recesses and protrusions of the roughened surface by heating the roughened surface,
wherein:
the implanting is performed after the roughening; and
the melting and the diffusing are simultaneously performed.

38. The method according to claim 35, further comprising:
forming a resin layer on the surface of the first substrate; and
forming an organic light-emitting laminate on a surface of the resin layer.
